(19) United States
(12) Patent Application Publication
(10) Pub. No.: US 2025/0114806 A1
(43) Pub. Date: Apr. 10, 2025

(54) SMART FACEPLATE/SHOWERHEAD USING SHAPE MEMORY ALLOY

(71) Applicant: Applied Materials, Inc., Santa Clara, CA (US)

(72) Inventors: Barath Kumar, Puducherry (IN); Sumesh Suresh, Bangalore (IN)

(73) Assignee: Applied Materials, Inc., Santa Clara, CA (US)

(21) Appl. No.: 18/482,658

(22) Filed: Oct. 6, 2023

(51) Int. Cl. B05B 1/16; F03G 7/06

(52) U.S. Cl. CPC B05B 1/169; F03G 7/0614

(57) ABSTRACT

Exemplary substrate processing system faceplates may include a plate that is characterized by a first surface and a second surface opposite the first surface. The second surface may define a plurality of recesses that extend through a portion of a thickness of the plate. The plate may define a plurality of apertures through the thickness of the plate. Each aperture may extend through a bottom surface of one recess of the plurality of recesses. Each recess may have a greater diameter than the aperture extending through the bottom surface of the recess. The faceplate may include a plurality of shape-memory actuators. Each shape-memory actuator may be seated within a respective one of the plurality of recesses. Each shape-memory actuator may define an actuator aperture. A diameter of the actuator aperture each shape memory actuator may be variable.

### TECHNICAL FIELD

The present technology relates to components and apparatuses for semiconductor manufacturing. More specifically, the present technology relates to processing chamber distribution components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

Exemplary substrate processing system faceplates may include a plate that is characterized by a first surface and a second surface opposite the first surface. The second surface may define a plurality of recesses that extend through a portion of a thickness of the plate. The plate may define a plurality of apertures through the thickness of the plate. Each aperture may extend through a bottom surface of one recess of the plurality of recesses. Each recess may have a greater diameter than the aperture extending through the bottom surface of the recess. The faceplate may include a plurality of shape-memory actuators. Each shape-memory actuator may be seated within a respective one of the plurality of recesses. Each shape-memory actuator may define an actuator aperture. A diameter of the actuator aperture each shape memory actuator may be variable.

In some embodiments, the faceplates may include a plurality of electrical lines coupled with the plate. Each electrical line may be electrically coupled with at least one of the shape-memory actuators. The diameter of the actuator aperture of each shape-memory actuator may be variable upon application of an electric current. The plurality of electrical lines may be arranged to provide a plurality of independently controllable zones. The plurality of independently controllable zones may include annular zones. The plurality of independently controllable zones may include radial zones. The faceplates may include a plurality of resistive heating lines coupled with the plate. Each resistive heating line may be electrically coupled with at least one of the shape-memory actuators. The diameter of the actuator aperture of each shape-memory actuator may be variable upon application of heat. Each shape-memory actuator may include Nitinol. Each shape-memory actuator may be generally cone shaped. Each shape-memory actuator may include a shape-memory inner material and a chamber-compatible outer material. The chamber-compatible outer material may include polytetrafluoroethylene. The shape-memory inner material may have a conical spring shape.

Some embodiments of the present technology may encompass substrate processing chambers. The chambers may include a chamber body. The chambers may include a substrate support disposed within the chamber body. The substrate support may define a substrate support surface. The chambers may include a faceplate supported atop the chamber body. The faceplate may include a plate that is characterized by a first surface and a second surface opposite the first surface. The second surface may define a plurality of recesses that extend through a portion of a thickness of the plate. The plate may define a plurality of apertures through the thickness of the plate. Each aperture may extend through a bottom surface of one recess of the plurality of recesses. Each recess may have a greater diameter than the aperture extending through the bottom surface of the recess. The faceplate may include a plurality of shape-memory actuators. Each shape-memory actuator may be seated within a respective one of the plurality of recesses. Each shape-memory actuator may define an actuator aperture. A diameter of the actuator aperture each shape memory actuator may be variable.

In some embodiments, the second surface may face the substrate support. The chambers may include at least one power source. The faceplate may include a plurality of electrical lines coupled with the plate. Each electrical line may be electrically coupled with the at least one power source. Each electrical line may be electrically coupled with at least one of the shape-memory actuators. The diameter of the actuator aperture of each shape-memory actuator may be variable upon application of an electric current. The chambers may include at least one power source. The faceplate may include a plurality of resistive heating lines coupled with the plate. Each resistive heating line may be electrically coupled with the at least one power source. Each resistive heating line may be electrically coupled with at least one of the shape-memory actuators. The diameter of the actuator aperture of each shape-memory actuator may variable upon application of heat.

Some embodiments of the present technology encompass methods of processing a substrate. The methods may include delivering electrical current to a faceplate. The faceplate may include a plurality of shape-memory actuators. Each shape-memory actuator may define an actuator aperture. The electrical current may set a diameter of each actuator aperture. The methods may include flowing a precursor into a processing chamber via the actuator apertures of the plurality of shape-memory actuators. The methods may include generating a plasma of the precursor within a processing region of the processing chamber. The methods may include depositing a material on a substrate positioned within the processing region.

In some embodiments, the methods may include determining a desired flow conductance profile through the faceplate. The methods may include adjusting the electrical current delivered to at least some of the plurality of shape-memory actuators to adjust the diameter of the actuator apertures of the at least some of the plurality of shape-memory actuators. At least some of the plurality of shape-memory actuators may have actuator apertures having different diameters. Delivering electrical current to a faceplate may include delivering the electrical current to at least some of the plurality of shape-memory actuators via one or more electrical lines. Delivering electrical current to a faceplate may include delivering the electrical current to one or more resistive heating elements of the faceplate. The one or more resistive heating elements may be coupled with at least some of the plurality of shape-memory actuators.

Such technology may provide benefits over conventional systems and techniques. For example, embodiments of the present technology may allow controlled deposition at various locations of a substrate. Additionally, the components may enable the flow conductance profile through a faceplate to be customized to help mitigate deposition non-uniformity issues based on various issues associated with a given chamber and/or chemistry. Embodiments may enable deposition rates to be controlled solely using adjustments to the sizes of apertures of the faceplate in some embodiments. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary processing chamber according to some embodiments of the present technology.

FIG. 3 shows a partial schematic cross-sectional view of a faceplate according to some embodiments of the present technology.

FIG. 3A illustrates a top plan schematic view of the faceplate of FIG. 3.

FIG. 3B illustrates a top plan schematic view of the faceplate of FIG. 3.

FIG. 3C illustrates a top plan schematic view of the faceplate of FIG. 3.

FIG. 4 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity. Many chambers include a characteristic process signature, which may produce residual non-uniformity across a substrate. Temperature differences, flow pattern uniformity, and other aspects of processing may impact the films on the substrate, creating film uniformity differences across the substrate for materials produced or removed. For example, turbulent deposition gas flow and/or misalignment of apertures of a blocker plate and faceplate of a gas box may lead to non-uniform flow of deposition gases. Similarly, the geometry and/or other factors of a substrate support and/or heater may result in thermal non-uniformity that may impact the deposition rate across the substrate. Thus, there may be a need to better control treatment processes such as deposition in one or more areas to combat these non-uniformity issues to improve film thickness uniformity across the substrate.

The present technology overcomes these challenges by incorporating a faceplate that includes a number of shape-memory actuators that control a size of the apertures formed through the faceplate. The control of the aperture size may enable the flow conductance through the faceplate to be adjusted to combat various non-uniformities that affect the film thickness profile. The aperture sizes may be adjusted prior to commencement of deposition processes and/or may be adjusted in situ. The actuators may be controlled in any pattern to combat radial, residual, and/or other non-uniformity profiles on wafer. The use of a faceplate with adjustable aperture sizes may enable a single faceplate to be used with numerous processing chamber components and/or chemistry, and may prevent the need to fabricate and swap out faceplates for a particular processing operation, which may help reduce waste and preserve manufacturing resources.

Although the remaining disclosure will routinely identify specific deposition and/or etch processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

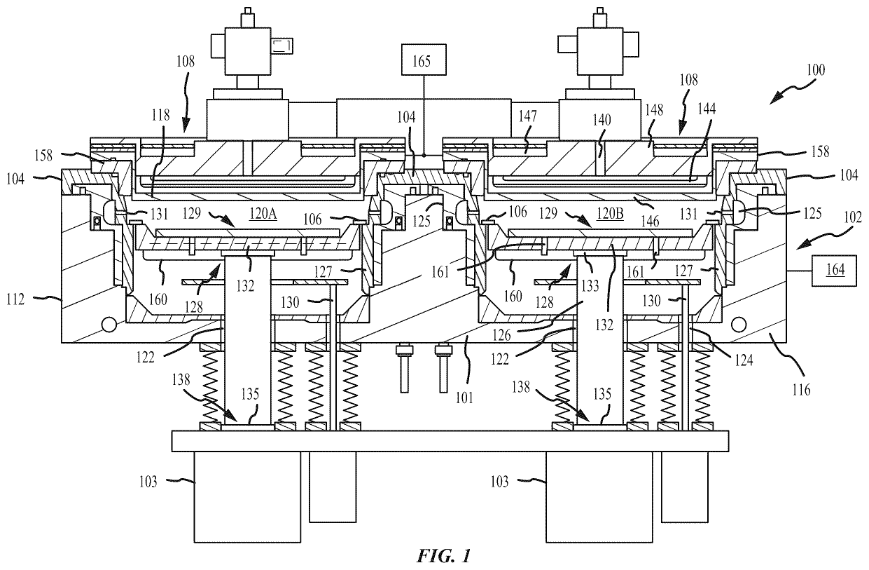

FIG. 1 shows a schematic cross-sectional view of an exemplary plasma enhanced processing system 100 according to some embodiments of the present technology. The plasma enhanced processing system 100 may illustrate a pair of processing chambers that may be fitted in one or more of tandem sections, and which may include substrate support assemblies according to embodiments of the present technology. The plasma enhanced processing system 100 generally may include a chamber body 102 having sidewalls 112, a bottom wall 116, and an interior sidewall 101 defining a pair of processing regions 120A and 120B. Each of the processing regions 120A-120B may be similarly configured and may include identical components.

For example, processing region 120B, the components of which may also be included in processing region 120A, may include a pedestal 128 disposed in the processing region through a passage 122 formed in the bottom wall 116 in the plasma enhanced processing system 100. The pedestal 128 may provide a heater adapted to support a substrate 129 on an exposed surface of the pedestal, such as a body portion. The pedestal 128 may include heating elements 132, for example resistive heating elements, which may heat and control the substrate temperature at a desired process temperature. Pedestal 128 may also be heated by a remote heating element, such as a lamp assembly, or any other heating device.

The body of pedestal 128 may be coupled by a flange 133 to a stem 126. The stem 126 may electrically couple the pedestal 128 with a power outlet or power box 103. The power box 103 may include a drive system that controls the elevation and movement of the pedestal 128 within the processing region 120B. The stem 126 may also include electrical power interfaces to provide electrical power to the pedestal 128. The power box 103 may also include interfaces for electrical power and temperature indicators, such as a thermocouple interface. The stem 126 may include a base assembly 138 adapted to detachably couple with the power box 103. A circumferential ring 135 is shown above the power box 103. In some embodiments, the circumferential ring 135 may be a shoulder adapted as a mechanical stop or land configured to provide a mechanical interface between the base assembly 138 and the upper surface of the power box 103.

A rod 130 may be included through a passage 124 formed in the bottom wall 116 of the processing region 120B and may be utilized to position substrate lift pins 161 disposed through the body of pedestal 128. The substrate lift pins 161 may selectively space the substrate 129 from the pedestal to facilitate exchange of the substrate 129 with a robot utilized for transferring the substrate 129 into and out of the processing region 120B through a substrate transfer port 160.

A chamber lid 104 may be coupled with a top portion of the chamber body 102. The lid 104 may accommodate one or more precursor distribution systems 108 coupled thereto. The precursor distribution system 108 may include a precursor inlet passage 140 which may deliver reactant and cleaning precursors through a showerhead 118 into the processing region 120B. The showerhead may include a single channel, or may include multiple channels (e.g., two, three, etc.). The showerhead 118 may include an annular base plate 148 having a blocker plate 144 disposed intermediate to a faceplate 146. A radio frequency (“RF”) source 165 may be coupled with the showerhead 118, which may power the showerhead 118 to facilitate generating a plasma region between the faceplate 146 of the showerhead 118 and the pedestal 128. In some embodiments, the RF source 165 may be coupled with the showerhead 118 directly or indirectly, such as via a strap or other connection extending between a gasbox and the showerhead 118. In some embodiments, the RF source may be coupled with other portions of the chamber body 102, such as the pedestal 128, to facilitate plasma generation. A dielectric isolator 158 may be disposed between the lid 104 and the dual-channel showerhead 118 to prevent conducting RF power to the lid 104. A shadow ring 106 may be disposed on the periphery of the pedestal 128 that engages the pedestal 128.

An optional cooling channel 147 may be formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 may be maintained at a predefined temperature. A liner assembly 127 may be disposed within the processing region 120B in close proximity to the sidewalls 101, 112 of the chamber body 102 to prevent exposure of the sidewalls 101, 112 to the processing environment within the processing region 120B. The liner assembly 127 may include a circumferential pumping cavity 125, which may be coupled to a pumping system 164 configured to exhaust gases and byproducts from the processing region 120B and control the pressure within the processing region 120B. A plurality of exhaust ports 131 may be formed on the liner assembly 127. The exhaust ports 131 may be configured to allow the flow of gases from the processing region 120B to the circumferential pumping cavity 125 in a manner that promotes processing within the system 100.

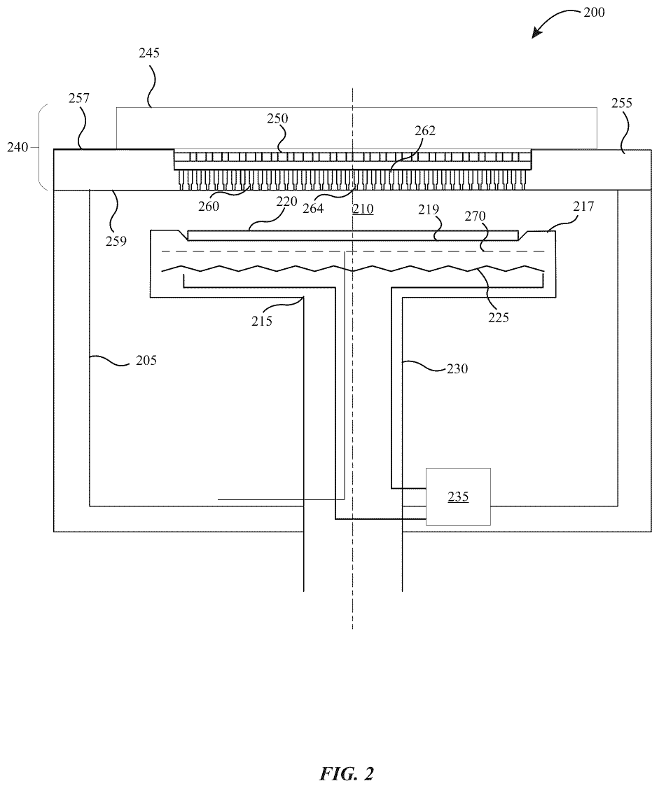

FIG. 2 shows a schematic cross-sectional view of a processing chamber 200 according to some embodiments of the present technology. FIG. 2 may include one or more components discussed above with regard to FIG. 1 and may illustrate further details relating to that chamber. The chamber 200 may be used to perform semiconductor processing operations including deposition of stacks of dielectric materials as previously described. Chamber 200 may show a partial view of a processing region of a semiconductor processing system, and may not include all of the components, such as additional lid stack components previously described, which are understood to be incorporated in some embodiments of chamber 200. The chamber 200 generally may include a chamber body 205 having sidewalls, a bottom wall, and an interior sidewall defining a processing region 210. Processing region 210 may include a substrate support 215 disposed in the processing region 210. The substrate support 215 may provide a heater adapted to support a substrate 220 on an exposed surface of the substrate support, such as a body portion. For example, the substrate support 215 may include a pocket 217 that defines an outer boundary of a substrate support surface 219. The pocket 217 may protrude upward from the substrate support 215, with a top surface of the pocket 217 being substantially aligned with a top surface of the substrate 220. For example, a top surface of the pocket 217 may be within or about 3% of a height of the top surface of the substrate 220, within or about 2% of the height of the top surface of the substrate 220, within or about 1% of the height of the top surface of the substrate 220, within or about 0.5% of the height of the top surface of the substrate 220, or less. For example, for a substrate 220 having a thickness of 1 mm, the height of the top surface of the pocket 217 may be between or about 0.970 mm and 1.030 mm, between or about 0.980 mm and 1.020 mm, between or about 0.990 mm and 1.010 mm, between or about 0.995 mm and 1.005 mm, or about 1 mm. The substrate support 215 may include heating elements 225, for example resistive heating elements, which may heat and control the substrate temperature at a desired process temperature. Substrate support 215 may also be heated by a remote heating element, such as a lamp assembly, or any other heating device.

The body of substrate support 215 may be to a stem 230. The stem 230 may

electrically couple the substrate support 215 with a power outlet or power box 235. The power box 235 may include a drive system that controls the elevation and movement of the substrate support 215 within the processing region 210. The stem 230 may also include electrical power interfaces to provide electrical power to the substrate support 215. The power box 235 may also include interfaces for electrical power and temperature indicators, such as a thermocouple interface. A precursor distribution assembly 240 may be coupled with a top portion of the chamber body 205, possibly with one or more intervening components positioned therebetween. The precursor distribution assembly 240 may deliver reactant and cleaning precursors into the processing region 210. The precursor distribution assembly 240 may include a gasbox 245, a blocker plate 250, and/or a faceplate 255. In some embodiments, the faceplate 255 may be heated, such as to a temperature of between about 70° C. and 350° C. The gasbox 245 may define or provide access into a processing chamber. Blocker plate 250 may be positioned between the gasbox 245 and the substrate support 215. The blocker plate 250 may include or define a number of apertures through the plate. In some embodiments the blocker plate may be characterized by increased central conductance. For example, in some embodiments a subset of apertures proximate or extending about a central region of the blocker plate may be characterized by a greater aperture diameter than apertures radially outward of the central region. This may increase a central flow conductance in some embodiments. A radio frequency (“RF”) source (not shown) may be coupled with the gas distribution assembly 240, which may power the gas distribution assembly 240 to facilitate generating a plasma region between the faceplate 255 and the substrate support 215. In some embodiments, the RF source may be coupled with other portions of the chamber body 205, such as the substrate support 215, to facilitate plasma generation. For example, an RF mesh or electrode 270 may be embedded within a body of the substrate support 215 which may be supplied with RF power to facilitate generation of plasma within the processing region 210.

The faceplate 255 (which may be similar to and/or used as faceplate 146 and/or showerhead 118) may be positioned within the chamber 200 between the blocker plate 250 and the substrate support 215 as illustrated previously. Faceplate 255 may be characterized by a first surface 257 and a second surface 259, which may be opposite the first surface 257. In some embodiments, first surface 257 may be facing towards a blocker plate 250, and/or gasbox 245. Second surface 259 may be positioned to face substrate support 215 within the processing region 210 of chamber 200. For example, in some embodiments, the second surface 259 of the faceplate 255 and the substrate support 215 may at least partially define the processing region 210. Faceplate 255 may define a plurality of apertures 260 defined through the faceplate 255 and extending from the first surface 257 through the second surface 259. Each aperture 260 may provide a fluid path through the faceplate 255, and the apertures 260 may provide fluid access to the processing region of the chamber. Apertures 260 may have generally cylindrical cross-sections in some embodiments. As illustrated, each aperture 260 may have an aperture profile that includes a larger upper cylindrical portion 262 and a smaller lower cylindrical portion 264, although other aperture profiles are possible in various embodiments. The upper cylindrical portion 262 may have a greater diameter than the lower cylindrical portion 264. For example, the upper cylindrical portion 262 may have a diameter that is about 1.5× to 3× as big as a diameter of the lower cylindrical portion 264. In some embodiments, the upper cylindrical portion 262 may have a diameter of between or about 0.025 inch and 0.1 inch, between or about 0.030 inch and 0.095 inch, between or about 0.035 inch and 0.090 inch, between or about 0.040 inch and 0.085 inch, between or about 0.045 inch and 0.080 inch, between or about 0.050 inch and 0.075 inch, between or about 0.060 inch and 0.070 inch, or between or about 0.060 inch and 0.065 inch. The lower cylindrical portion 264 may have a diameter of between or about 0.0075 inch and 0.050 inch, between or about 0.010 inch and 0.045 inch, between or about 0.015 inch and 0.040 inch, between or about 0.020 inch and 0.035 inch, or between or about 0.025 inch and 0.030 inch. In some embodiments, a length of all or substantially all (e.g., a central hole may be different) of the lower cylindrical portions 264 may be the same or substantially the same to promote uniform gas flow conductance through the faceplate 255. For example, a length of the lower cylindrical portion 264 may be between or about 0.025 inch and 0.500 inch, between or about 0.050 inch and 0.250 inch, or between or about 0.075 inch and 0.100 inch. As will be discussed in greater detail below, a length of the upper cylindrical portion 262 may be adjusted from aperture 260 to aperture 260 to accommodate lower cylindrical portions 264 having a same length.

In some embodiments, a flow conductance through substantially all of the plurality of apertures may be substantially equal. For example, flow conductance may be driven by the relationship of D⁴/L, where D is a smallest diameter of a given aperture (e.g., lower cylindrical portion 264) and L is a length of such a portion of the aperture. All or substantially all (e.g., at least 90%, at least 95%, at least 99%, all but one aperture (e.g., a centermost aperture), or all apertures) may have an equal or substantially equal (e.g., within 10%, within 5%, within 3%, within 1%, or less) flow conductance across the surface of the faceplate 255.

Depending on the size of the faceplate 255, and the size of the apertures 260, faceplate 255 may define any number of apertures 260 through the plate, such as greater than or about 1,000 apertures, greater than or about 2,000 apertures, greater than or about 3,000 apertures, greater than or about 4,000 apertures, greater than or about 5,000 apertures, greater than or about 6,000 apertures, or more. As noted above, the apertures 260 may be included in a set of rings extending outward from a central axis of the faceplate 255 and may include any number of rings as described previously. The rings may be characterized by any number of shapes including circular or elliptical, as well as any other geometric pattern, such as rectangular, hexagonal, or any other geometric pattern that may include apertures distributed in a radially outward number of rings. The apertures may have a uniform or staggered spacing and may be spaced apart at less than or about 10 mm from center to center. The apertures may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, apertures may be characterized by a scaling function of apertures per ring. For example, in some embodiments a first aperture may extend through a center of the faceplate, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number, as will be described further below where the first ring has an augmented number of apertures. For example, for an exemplary faceplate having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 50 rings. In some embodiments each aperture of the plurality of apertures across the faceplate may be characterized by an aperture profile, which may be the same or different in embodiments of the present technology.

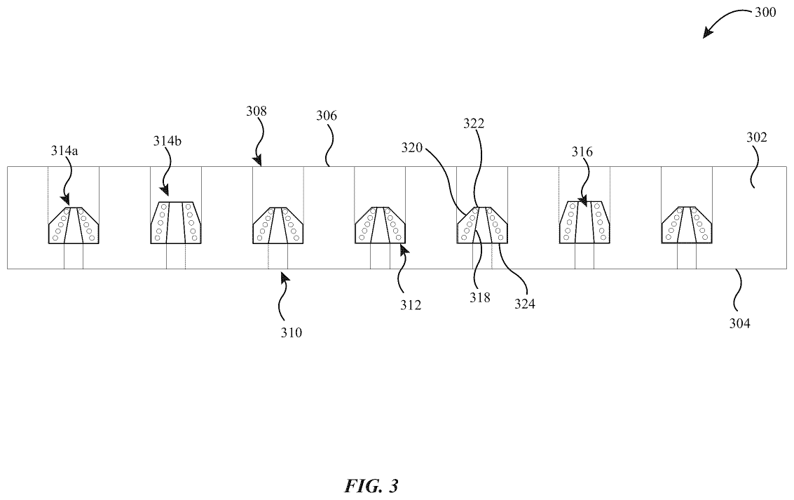

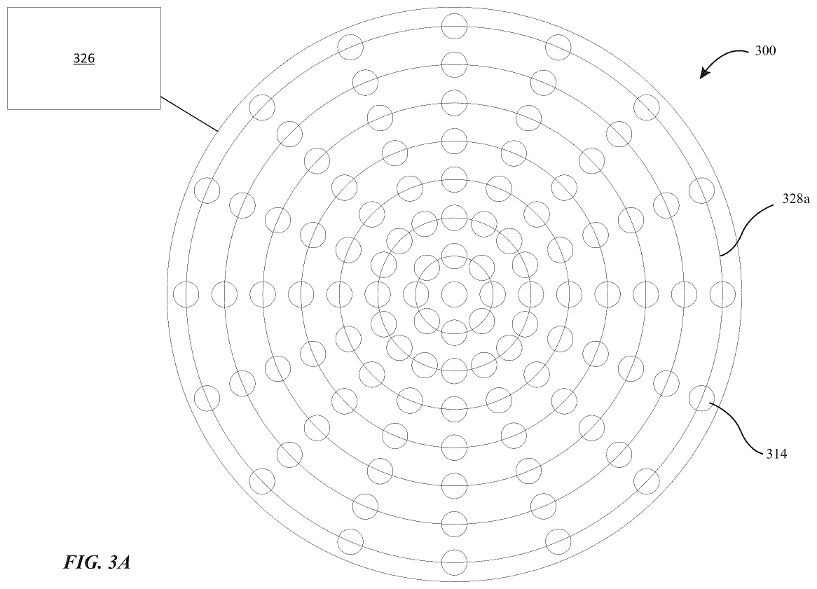

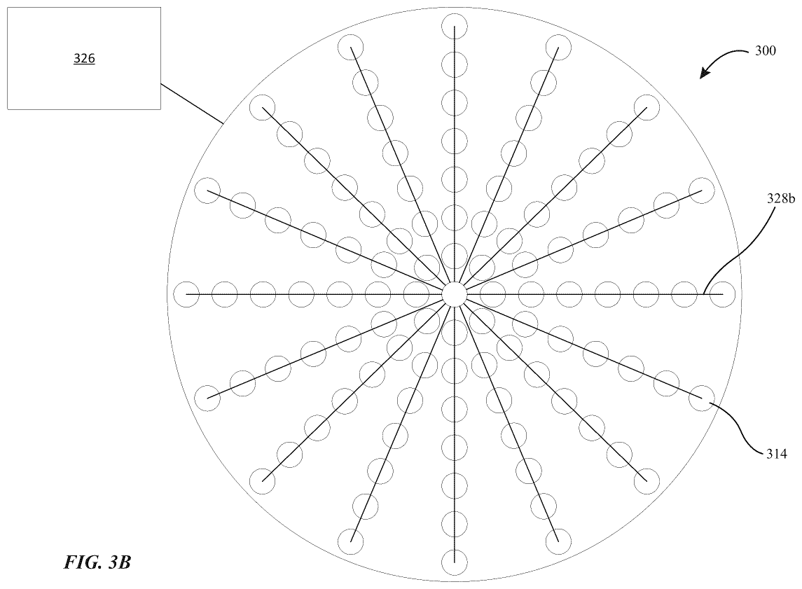

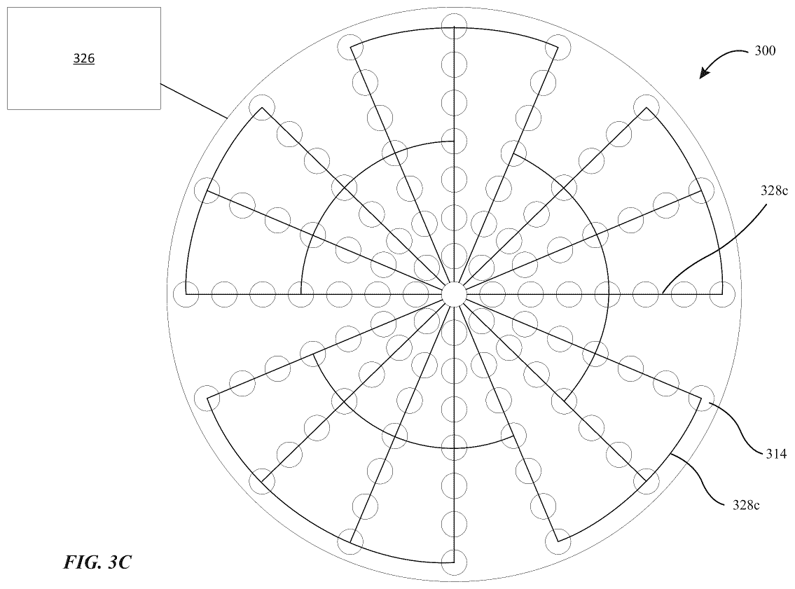

FIG. 3 shows a schematic cross-sectional view of a faceplate 300 according to some embodiments of the present technology. Faceplate 300 may be used as faceplate 146, showerhead 118, and/or faceplate 255 as discussed above with regard to FIGS. 1 and 2 and may illustrate further details relating to that faceplate. Faceplate 300 may include a plate 302, which may be formed from a conductive material in some embodiments. Plate 302 may be characterized by a first surface 304 and a second surface 306 opposite the first surface 304. In some embodiments, the first surface 304 may be a top surface of the plate 302 and may face an upstream side of a processing chamber, with the second surface 306 facing a substrate support of the processing chamber. For example, in some embodiments, the second surface 306 of the plate 302 and the substrate support may at least partially define a processing region of the processing chamber. In other embodiments, the orientation of first and second surfaces may be reversed. As illustrated, the second surface 306 of the plate 302 may define a number of recesses 308. Each recess 308 may extend through a portion of a thickness of the plate 302, such as extending from second surface 306 toward the first surface 304 without extending through the first surface 304. Each recess 308 may have generally cylindrical cross-section in some embodiments, although other shapes are possible.

Depending on the size of the faceplate 300, and the size of the recesses 308, faceplate 300 may define any number of recesses 308 through the plate 302, such as greater than or about 1,000 recesses, greater than or about 2,000 recesses, greater than or about 3,000 recesses, greater than or about 4,000 recesses, greater than or about 5,000 recesses, greater than or about 6,000 recesses, or more. The recesses 308 may be distributed about the second surface 306 in a pattern similar to apertures 260 of faceplate 255. For example, the recesses 308 may be included in a set of rings extending outward from a central axis of the faceplate 300 and may include any number of rings as described previously. The rings may be characterized by any number of shapes including circular or elliptical, as well as any other geometric pattern, such as rectangular, hexagonal, or any other geometric pattern that may include recesses distributed in a radially outward number of rings. The recesses may have a uniform or staggered spacing and may be spaced apart at less than or about 10 mm from center to center. The recesses may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, recesses may be characterized by a scaling function of recess per ring. For example, in some embodiments a first recess may extend through a center of the faceplate, such as along the central axis as illustrated. A first ring of recesses may extend about the central recess, and may include any number of recesses, such as between about 4 and about 10 recesses, which may be spaced equally about a geometric shape extending through a center of each aperture. Any number of additional rings of recesses may extend radially outward from the first ring and may include a number of recesses that may be a function of the number of recesses in the first ring. For example, the number of recesses in each successive ring may be characterized by a number of recesses within each corresponding ring according to the equation XR, where X is a base number of recesses, and R is the corresponding ring number. The base number of recesses may be the number of recesses within the first ring, and in some embodiments may be some other number, as will be described further below where the first ring has an augmented number of recesses. For example, for an exemplary faceplate having 5 recesses distributed about the first ring, and where 5 may be the base number of recesses, the second ring may be characterized by 10 recesses, (5)×(2), the third ring may be characterized by 15 recesses, (5)×(3), and the twentieth ring may be characterized by 100 recesses, (5)×(20). This may continue for any number of rings of recesses as noted previously, such as up to, greater than, or about 50 rings.

The plate 302 may define a number of apertures 310 through the thickness of the plate 302. For example, a bottom surface or base of each recess 308 may define an aperture 310 that extends through the bottom surface of the recess 308 and through the first surface 304 of the plate 302. Each aperture 310 may be centered with respect to the corresponding recess 308 in some embodiments, although in some embodiments the aperture 310 may be offset relative to the central axis of the corresponding recess 308. Each recess 308 may have a greater diameter than the aperture 310 extending through the bottom surface of the recess 308. This may enable the base of the recess 308 to define a shelf 312 that faces away from the first surface 304.

Faceplate 300 may include a number of shape-memory actuators 314. Each shape-memory actuator 314 may be seated within a respective one of the recesses 308, such as against shelf 312. In some embodiments, each recess 308 may include a dedicated shape-memory actuator 314. Each shape-memory actuator 314 may define an actuator aperture 316 that extends through a thickness of the shape-memory actuator 314. When the shape-memory actuator 314 is inserted within the recess 308, the actuator aperture 316 may be aligned with aperture 310 defined through the recess 308. This may enable recess 308, aperture 310, and actuator aperture 316 to provide a fluid path through the faceplate 300 for delivering gases, plasmas, and/or other fluids to the processing region of the chamber. In some embodiments, the actuator aperture 316 may be sized such that the actuator aperture 316 is smaller than aperture 310, which may enable the actuator aperture 316 to control the flow conductance through the aperture 310.

The shape-memory actuator 314 may be configured to change shape upon application of an external stimulus, which may enable a diameter of the actuator aperture 316 to be varied or otherwise adjusted. The adjustment of the diameter of the actuator aperture 316 may enable the flow conductance through the actuator aperture 316 (and subsequently, the faceplate 300) to be carefully controlled. For example, the application of the external stimulus may be applied to one or more of the shape-memory actuators 314 to expand or contract a size of the diameter of the actuator aperture 316. In some embodiments, the diameters of the actuator apertures 316 may be variable between 1 mil and 1000 mils, 5 mils and 500 mils, 10 mils and 100 mils, and/or any ranges of values therebetween.

Each shape-memory actuator 314 may include a shape-memory material that may move between one shape and/or size to another (or range of sizes and shapes) upon application or removal of an external stimulus (such as heat and/or electrical current). In some embodiments, the shape-memory material may include nickel-titanium alloys (e.g., Nitinol), nickel-titanium-cobalt alloys, nickel-titanium-copper alloys, copper-aluminum-nickel alloys, and/or other shape-memory materials, which may include nickel, titanium, zinc, copper, gold, iron, and/or other materials. In some embodiments, the shape-memory material may not be compatible with the chamber environment/chemistry for a given operation. To alleviate such issues, each shape-memory actuator 314 may include an outer layer, coating, or other material that may protect or otherwise isolate the shape-memory material from the chamber environment. For example, each shape-memory actuator 314 may include a shape-memory inner material and a chamber-compatible outer material. The chamber-compatible may include an elastic, malleable, and/or otherwise deformable material that protects the shape-memory material while still permitting the shape-memory material to change shape and/or size. In some embodiments, the chamber-compatible material may be a polymeric material, such as polytetrafluoroethylene (PTFE).

The shape-memory material may take many forms. For example, in the illustrated embodiment the shape-memory material has a conical spring shape. As the stimulus is applied to the shape-memory material, the steepness of the conical spring shape is altered, resulting in a change in the diameter of the actuator aperture 316. For example, as illustrated shape-memory actuator 314a is shown in an unstimulated configuration, while shape-memory actuator 314b is shown in a stimulated configuration. In the stimulated configuration, shape-memory actuator 314b has a greater steepness, which results in an expansion of the diameter of the actuator aperture 316 of shape-memory actuator 314b. It will be appreciated that in various embodiments, the stimulated configuration may cause the diameter of the actuator aperture 316 of shape-memory actuator 314b to contract. In some embodiments, the operation of the shape-memory actuator 314 may be binary, such that stimulus may cause the shape-memory actuator 314 to move from a first, neutral position to a second, actuated position, with no intermediate positions. Such operation may be usable to adjust the actuator aperture 316 between a first diameter and a second diameter. In other embodiments, the operation of the shape-memory actuator 314 may be gradual, such that stimulus may cause the shape-memory actuator 314 to move from a first, neutral position to a second, actuated position, with any number of intermediate positions (e.g., at regular or irregular intervals, a gradual transition, and/or other transition). Such operation may be usable to adjust the actuator aperture 316 to any of a number of diameters between a minimum diameter and a maximum diameter and may enable the diameter of the actuator aperture to be more precisely and finely tuned and may provide greater control of the flow conductance through all or a portion (including a single aperture 310) of the faceplate 300. The diameter of the actuator aperture 316 may be measured at a smallest point of the respective aperture. For example, where the shape-memory actuator 314 is generally cone-shaped, the diameter of the actuator aperture 316 may be measured proximate a narrow end of the cone shape.

As noted above, the shape-memory actuators 314 may take various forms. In the illustrated embodiment the shape-memory actuators 314 are generally cone-shaped and include a conical spring shaped shape-memory inner material and a generally cone or conical frustum shaped chamber-compatible outer material that defines a general shape of the respective shape-memory actuator 314. Each shape-memory actuator 314 may include one or more inner walls 318, one or more outer walls 320, a top end 322, and a bottom end 324. Bottom end 324 may be generally planar in some embodiments and may be positioned against the bottom surface of one of the recesses 308, such as seated against shelf 312. The inner wall 318 may define the actuator aperture 316. In the illustrated embodiment, the inner wall 318 is generally conical frustum shaped, although other shaped walls, including cylindrical walls, may be utilized. In some embodiments, a bottom end of the actuator aperture 316 may match or substantially match (e.g., within 10%, within 5%, within 3%, within 1%) a diameter of aperture 310, while in other embodiments a diameter of the actuator aperture 316 may be smaller or greater than aperture 310. In some embodiments, at least a portion of the outer walls 320 may be in contact with lateral walls of the recess 308 at all times, including when the shape-memory actuator 314 is in an unstimulated configuration. For example, as illustrated, a bottom portion of the outer wall 320 may be generally cylindrical and may abut the lateral walls of the recess 308 in both the unstimulated and stimulated configurations. Such a design may help maintain the shape-memory actuator 314 at a desired position within the recess 308 even during operation (e.g., re-sizing and/or re-shaping) of the shape-memory actuator 314. In the illustrated embodiment, a top portion of the outer wall 320 has a conical frustum shape, although other designs are possible in various embodiments. In some embodiments, a thickness of the shape-memory actuator 314 may vary along a length of the shape-memory actuator 314. For example, in the illustrated embodiment, the shape-memory actuator 314 has a greater thickness proximate bottom end 324 and tapers to a narrower thickness at the top end 322. Such a design may help ensure that the top end 322 (which defines the narrowest portion of the actuator aperture 316 and subsequently the flow conductance through the shape-memory actuator 314) is sufficiently pliable to vary the diameter of the actuator aperture 316, while the thicker bottom end 324 may provide strength and rigidity to the shape-memory actuator 314 and maintain the shape-memory actuator 314 in a desired position within the recess 308.

In some embodiments, the shape-memory actuators 314 may be sized such that in both an unstimulated configuration and a fully stimulated configuration, the top end 322 remains at or below a boundary of the recess 308. In other embodiments, the top end 322 may extend beyond the boundary of the recess 308 in the unstimulated configuration and/or the fully stimulated configuration.

As best illustrated in FIGS. 3A-3C, the faceplate 300 may include a number of stimulus lines 328 that may couple the shape-memory actuators 314 with one or more sources of a stimulus. For example, in some embodiments the stimulus lines 328 may be electrical lines that are each electrically coupled with at least one of the shape-memory actuators 314. Each electrical line may deliver electric current to one or more of the shape-memory actuators 314. The electric current may be a stimulus that causes the shape-memory actuators 314 to change size and/or shape. For example, electric current may cause the cone shape of the shape-memory actuator 314 to get flatter or steeper to increase or decrease a diameter of the actuator aperture 316. In other embodiments, the stimulus lines 328 may be resistive heating lines that are each coupled with at least one of the shape-memory actuators 314. Each resistive heating line may heat one or more of the shape-memory actuators 314. The heat may be a stimulus that causes the shape-memory actuators 314 to change size and/or shape. For example, the application of heat may cause the cone shape of the shape-memory actuator 314 to get flatter or steeper to increase or decrease a diameter of the actuator aperture 316.

Each stimulus line 328 may be coupled with one or more power sources 326 that may supply electric current to the stimulus lines 328. The electric current may be supplied to the shape-memory actuators 314 (e.g., when the stimulus line 328 is an electrical line) and/or may be converted to heat for delivery to the shape-memory actuators 314 (e.g., when the stimulus line 328 is a resistive heating line). In some embodiments, each stimulus line 328 within faceplate 300 may be a same type of stimulus line 328, while in other embodiments a mix of different types of stimulus lines (e.g., electrical line, resistive heating line, and/or other type of stimulus line) may be utilized in a single faceplate 300.

The stimulus lines 328 may be provided in various forms. For example, some or all of the stimulus lines 328 may be printed, deposited, and/or otherwise formed on and/or coupled with the first surface 304 or the second surface 306. In some embodiments, some or all of the stimulus lines 328 may be formed or otherwise positioned within an interior of the plate 302. A portion of each stimulus line 328 may be positioned proximate and/or in contact with one or more of the shape-memory actuators 314. As just one example, a portion of each stimulus line 328 may extend into and couple with a portion of a recess 308 and/or a shape-memory actuator 314 (and possibly shape-memory material thereof) disposed within the recess 308. In some embodiments the stimulus lines 328 may be wires, coils, and/or other pieces of metal or other electrically and/or thermally conductive material.

The stimulus lines 328 may be arranged about the faceplate 300 to provide a number of independently controllable zones. For example, an amount of current or power delivered to each zone may be varied to control the actuation of the shape-memory actuators 314, and subsequently the diameters of the actuator apertures 316, within a given zone. In some embodiments, each zone may receive a same amount of electric current (or electric current per shape-memory actuator 314 in a given zone), while in other instances some or all of the zones may receive different amounts of electric current (or electric current per shape-memory actuator 314 in a given zone). The use of independently controlled zones may therefore enable the diameters of the actuator apertures 316 within a given zone to be carefully controlled to provide a desired flow conductance profile through the faceplate 300. The faceplate 300 may include any number of zones, with greater numbers of zones providing greater granularity in the control of the flow conductance profile through the faceplate 300. For example, the faceplate 300 may include at least two zones, at least three zones, at least four zones, at least five zones, at least six zones, at least seven zones, at least eight zones, at least nine zones, at least ten zones, at least twenty zones, at least thirty zones, at least forty zones, at least fifty zones, or more. In some embodiments, each shape-memory actuator 314 may include a dedicated stimulus line 328 and may form a full zone. In some embodiments, each shape-memory actuator 314 may be coupled with a single stimulus line 328 and be part of a single zone, while in other embodiments some or all of the shape-memory actuators 314 are coupled with multiple stimulus lines 328 and may form a portion of multiple zones.

The zones may be arranged in various forms to address various non-uniformity issues. For example, as illustrated in FIG. 3A, stimulus lines 328a are arranged as a number of annular zones that are coaxial with one another. Each zone may be an annular shape that includes one or more rings of shape-memory actuators 314. Such stimulus lines 328a may be used to combat radial uniformity issues. As illustrated in FIG. 3B, stimulus lines 328b are arranged as a number of radial zones. For example, each zone may include stimulus lines 328b extending radially outward from at or near a center of the faceplate 300 and/or extending radially inward from at or near an edge of the faceplate 300, with each zone including one or more radial lines of shape-memory actuators 314. Such stimulus lines 328b may be used to combat residual uniformity issues. As illustrated in FIG. 3C, stimulus lines 328c are arranged as a combination of radial zones and arcuate zones. The radial zones may extend from an innermost row/ring of shape-memory actuators 314 to an outermost row/ring of shape-memory actuators 314 and/or may extend along only a portion of the rows/rings of shape-memory actuators and arcuate zones may extend 360 degrees entirely about a central axis of the faceplate 300 (i.e., be annular) or may extend less than 360 degrees about the central axis of the faceplate 300.

While shown as being arranged in a symmetrical manner, it will be appreciated that the zones of stimulus lines 328 may be arranged asymmetrically in some embodiments. The zones may be defined by a radial and/or angular position, a number of apertures, and/or any other criteria. In some embodiments, a number of shape-memory actuators 314 within each zone may be equal, while in other embodiments some or all of the zones may include different numbers of shape-memory actuators 314.

While shown here as being a single channel faceplate (e.g., all materials passing through the faceplate 300 pass through a same set of actuator apertures 316), it will be appreciated that faceplate 300 may be a dual-channel and/or other multi-channel faceplate in some embodiments. In such embodiments, the faceplate 300 may define at least one additional set of apertures that may form a separate flow path for another material to flow through without mixing with the material flowing through the actuator apertures 316 within the faceplate 300. In some embodiments, the additional apertures may have fixed diameters and/or may include an additional set of shape-memory actuators (which may be formed in a similar manner to that described herein). In single channel embodiments, faceplate 300 may include only apertures 310 that are aligned with shape-memory actuators 314 and/or may also include a subset of apertures having fixed diameters.

The use of shape-memory actuators 314 may enable the flow conductance through the faceplate 300 to be customized to meet the needs of a particular processing chamber and/or deposition/etch chemistry. Incorporating shape-memory actuators 314 into faceplates 300 may eliminate or reduce the need to swap out faceplates with different aperture layouts when a processing chemistry is changed and may improve the efficiency of such transitions while reducing the resources needed for fabricating faceplates, as a single faceplate design may be used for a wide variety of processing chambers/applications. The flow conductance through one or more zones of the faceplate 300 may be adjusted to address various film thickness uniformity issues, and the adjustments may be made prior to commencement of deposition operations and/or in situ. As just one example, one or more substrates may be processed with a given flow conductance profile. A film thickness profile may be generated from the substrates, and the film thickness profile may be analyzed to determine where deposition rates were too high and/or low. The diameters of actuator apertures 316 within one or more zones of the faceplate 300 may be adjusted based on this analysis to alter the flow conductance and deposition rate to combat various areas of film thickness non-uniformity.

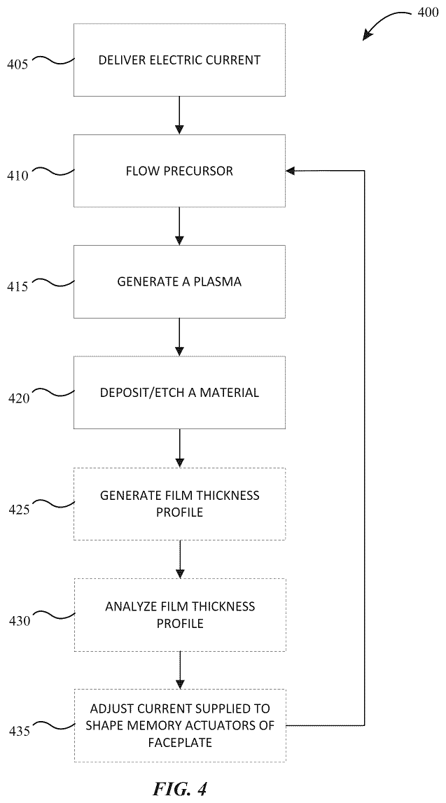

FIG. 4 shows operations of an exemplary method 400 of semiconductor processing according to some embodiments of the present technology. The method may be performed in a variety of processing chambers, including processing chamber 200 described above, which may include faceplates according to embodiments of the present technology, such as faceplate 300. Method 400 may include a number of optional operations, which may or may not be specifically associated with some embodiments of methods according to the present technology.

Method 400 may include a processing method that may include operations for forming a hardmask film or other deposition operations. The method may include optional operations prior to initiation of method 400, or the method may include additional operations. For example, method 400 may include operations performed in different orders than illustrated. In some embodiments, method 400 may include delivering electrical current to a faceplate at operation 405. The electrical current may be used to adjust the diameter of actuator apertures of shape-memory actuators (such as shape-memory actuator 314) to control the flow conductance through the faceplate. For example, in some embodiments, the electrical current may be delivered to some or all of the shape-memory actuators to change the diameter of the respective actuator apertures. In other embodiments, the electrical current may be used to heat one or more resistive heating lines that are positioned proximate some or all of the shape-memory actuators. The heat from the resistive heating lines may cause the diameter of the respective actuator apertures to change. The electric current and/or heat stimulus may be delivered to the shape-memory actuators via a number of stimulus lines (e.g., electrical lines and/or resistive heating lines) that are coupled with the faceplate. The diameters of the actuator apertures may be controlled in any number of independently controllable zones, which may enable the flow conductance profile through the faceplate to be varied to meet the needs of a particular application to achieve a desired film thickness profile. For example, some of the shape-memory actuators may have actuator apertures having different diameters to combat film thickness uniformity issues.

In some embodiments, method 400 may include flowing one or more precursors into a processing chamber via the actuator apertures of the shape-memory actuators (and/or other apertures) at operation 410. For example, the precursor may be flowed into a chamber, such as chamber 200, and may flow the precursor through one or more of a gasbox, a blocker plate, or a faceplate (such as faceplate 300), prior to delivering the precursor into a processing region of the chamber. At operation 415, a plasma may be generated of the precursors within the processing region, such as by providing RF power to the faceplate to generate a plasma. Material formed in the plasma may be deposited on the substrate at operation 420.

In some embodiments, method 400 may optionally include determining a desired flow conductance profile through the faceplate. For example, one or more substrates (such as sample substrates) may be processed with a given flow conductance profile. A film thickness profile showing any non-uniformities may be generated from the substrates at optional operation 425, and the film thickness profile may be analyzed at optional operation 430 to determine where deposition rates were too high and/or low. Method 400 may include adjusting the electrical current delivered to at least some of the plurality of shape-memory actuators at optional operation 435 to adjust the diameter of the actuator apertures of the at least some of the plurality of shape-memory actuators based on the analysis. Such adjustments may alter the flow conductance and deposition rate to combat various areas of film thickness non-uniformity. The process of analyzing film thickness profiles and adjusting the current may be performed any number of times until the processed substrates have a desired film thickness profile.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate processing system faceplate, comprising:
a plate that is characterized by a first surface and a second surface opposite the first surface, wherein:
the second surface defines a plurality of recesses that extend through a portion of a thickness of the plate;
the plate defines a plurality of apertures through the thickness of the plate; and
each aperture extends through a bottom surface of one recess of the plurality of recesses; and
a plurality of shape-memory actuators, wherein:
each shape-memory actuator is seated within a respective one of the plurality of recesses;
each shape-memory actuator defines an actuator aperture; and
a diameter of the actuator aperture each shape memory actuator is variable.

2. The substrate processing system faceplate of claim 1, further comprising:
a plurality of electrical lines coupled with the plate, wherein:
each electrical line is electrically coupled with at least one of the shape-memory actuators; and
the diameter of the actuator aperture of each shape-memory actuator is variable upon application of an electric current.

3. The substrate processing system faceplate of claim 2, wherein:
the plurality of electrical lines are arranged to provide a plurality of independently controllable zones.

4. The substrate processing system faceplate of claim 3, wherein:
the plurality of independently controllable zones comprise annular zones.

5. The substrate processing system faceplate of claim 3, wherein:
the plurality of independently controllable zones comprise radial zones.

6. The substrate processing system faceplate of claim 1, further comprising:
a plurality of resistive heating lines coupled with the plate, wherein:
each resistive heating line is electrically coupled with at least one of the shape-memory actuators; and
the diameter of the actuator aperture of each shape-memory actuator is variable upon application of heat.

7. The substrate processing system faceplate of claim 1, wherein:
each shape-memory actuator comprises Nitinol.

8. The substrate processing system faceplate of claim 1, wherein:
each shape-memory actuator is generally cone shaped.

9. The substrate processing system faceplate of claim 1, wherein:
each shape-memory actuator comprises a shape-memory inner material and a chamber-compatible outer material.

10. The substrate processing system faceplate of claim 9, wherein:
the chamber-compatible outer material comprises polytetrafluoroethylene.

11. The substrate processing system faceplate of claim 9, wherein:
the shape-memory inner material has a conical spring shape.

12. A substrate processing chamber, comprising:
a chamber body;
a substrate support disposed within the chamber body; and
a faceplate supported atop the chamber body, the faceplate comprising a plate that is characterized by a first surface and a second surface opposite the first surface, wherein:
the second surface defines a plurality of recesses that extend through a portion of a thickness of the plate;
the plate defines a plurality of apertures through the thickness of the plate; and
each aperture extends through a bottom surface of one recess of the plurality of recesses; and
a plurality of shape-memory actuators, wherein:
each shape-memory actuator is seated within a respective one of the plurality of recesses;
each shape-memory actuator defines an actuator aperture; and
a diameter of the actuator aperture each shape memory actuator is variable.

13. The substrate processing chamber of claim 12, wherein:
the second surface faces the substrate support.

14. The substrate processing chamber of claim 12, further comprising:
at least one power source, wherein:
the faceplate comprises a plurality of electrical lines coupled with the plate;
each electrical line is electrically coupled with the at least one power source;
each electrical line is electrically coupled with at least one of the shape-memory actuators; and
the diameter of the actuator aperture of each shape-memory actuator is variable upon application of an electric current.

15. The substrate processing chamber of claim 12, further comprising:
at least one power source, wherein:
the faceplate comprises a plurality of resistive heating lines coupled with the plate;
each resistive heating line is electrically coupled with the at least one power source;
each resistive heating line is electrically coupled with at least one of the shape-memory actuators; and
the diameter of the actuator aperture of each shape-memory actuator is variable upon application of heat.

16. A method of processing a substrate, comprising:
delivering electrical current to a faceplate, wherein:
the faceplate comprises a plurality of shape-memory actuators, each shape-memory actuator defining an actuator aperture; and
the electrical current sets a diameter of each actuator aperture;
flowing a precursor into a processing chamber via the actuator apertures of the plurality of shape-memory actuators; and
generating a plasma of the precursor within a processing region of the processing chamber.

17. The method of processing a substrate of claim 16, further comprising:
determining a desired flow conductance profile through the faceplate; and
adjusting the electrical current delivered to at least some of the plurality of shape-memory actuators to adjust the diameter of the actuator apertures of the at least some of the plurality of shape-memory actuators.

18. The method of processing a substrate of claim 16, wherein:
at least some of the plurality of shape-memory actuators have actuator apertures having different diameters.

19. The method of processing a substrate of claim 16, wherein:
delivering electrical current to a faceplate comprises delivering the electrical current to at least some of the plurality of shape-memory actuators via one or more electrical lines.

20. The method of processing a substrate of claim 16, wherein:
delivering electrical current to a faceplate comprises delivering the electrical current to one or more resistive heating elements of the faceplate, wherein the one or more resistive heating elements are coupled with at least some of the plurality of shape-memory actuators.
